(19) United States
(12) Patent Application Publication
(10) Pub. No.: US 2020/0187354 A1
(43) Pub. Date: Jun. 11, 2020

(54) STRUCTURE FOR SOLDERING A SOLDERING FASTENING ELEMENT TO CIRCUIT BOARD

(71) Applicant: DTECH PRECISION INDUSTRIES CO., LTD., NEW TAIPEI CITY (TW)

(72) Inventor: TING-JUI WANG, NEW TAIPEI CITY (TW)

(21) Appl. No.: 16/789,910

(22) Filed: Feb. 13, 2020

Related U.S. Application Data
(62) Division of application No. 15/132,357, filed on Apr. 19, 2016.

(51) Int. Cl. H05K 1/14; H05K 3/36

(52) U.S. Cl. CPC H05K 1/144; H05K 3/34; H05K 2201/10303; H05K 3/368

(57) ABSTRACT

A soldering fastening element, a structure thereof and a method for soldering the soldering fastening element to a circuit board are introduced. The soldering fastening element is soldered to a first circuit board so as for a second board to be coupled thereto. The soldering fastening element includes a body soldered to the first circuit board, a head for fastening the second board in place, and a neck which connects the body and the head. When in use, the soldering fastening element is contained in a carrier, taken out of the carrier with an automated tool, transferred to the first circuit board, and heated through a solder layer on the first circuit board such that the body gets soldered to the first circuit board to form a module member. Therefore, the second board gets coupled to the first circuit board through the head and neck.

### CROSS-REFERENCE TO RELATED APPLICATION

This application is a divisional patent application of U.S. application Ser. No. 15/132,357 filed on Apr. 19, 2016, the entire contents of which are hereby incorporated by reference for which priority is claimed under 35 U.S.C. § 120.

### BACKGROUND OF THE INVENTION

### 1. Field of the Invention

The present invention relates to a soldering fastening element, a structure thereof and a method for soldering the soldering fastening element to a circuit board to not only allow the soldering fastening element and a first circuit board to form a module member collectively but also enable a second board to be fixed in place through the soldering fastening element.

### 2. Description of the Related Art

Conventional techniques whereby two circuit boards are coupled together usually entail coupling the two circuit boards with screws, for example, forming multiple screw holes on the first circuit board, screwing connection posts each having an external thread post at one end and an internal thread hole at the other end to the screw holes of the first circuit board, respectively, forming multiple optical holes on the second board intended to be coupled to the first circuit board, placing the second board on the connection posts, passing multiple screws through the optical holes of the second board, and screwing the multiple screws to the holes of the connection posts, thereby coupling the two circuit boards together.

However, the aforesaid structure whereby connection posts are screwed to the first circuit board requires screwing the connection posts to the screw holes of the first circuit board one by one, respectively, thereby slowing down the assembly process. Furthermore, to couple the second board to the first circuit board, it is necessary to tighten the screws one by one, thereby deteriorating the assembly efficiency. Last but not least, in the situation where two circuit boards have to be mounted and demounted very often, the aforesaid screwing technique fails to meet the requirement of the ease of mounting and demounting.

### BRIEF SUMMARY OF THE INVENTION

In view of the drawbacks of the prior art, the inventor of the present invention recognized room for improvement and thus conducted extensive researches and experiments according to the inventor's years of experience in the related industry, and finally developed a soldering fastening element, a structure thereof and a method for soldering the soldering fastening element to a circuit board, so as to simplify the assembly structures and enhance the production yield.

In order to achieve the above and other objectives, the present invention provides a soldering fastening element, soldered to a first circuit board to allow a second board to be coupled thereto, the soldering fastening element comprising: a body soldered to a first solder layer of the first circuit board; a head for fastening the second board in place; and a neck for connecting the body and the head.

Regarding the soldering fastening element, the body has an engaging surface for engaging with a surface of the first circuit board and has a second solder layer which a solder paste can be applied thereto.

Regarding the soldering fastening element, the body has a protruding portion penetratingly disposed in an opening of the first circuit board and has a second solder layer which a solder paste can be applied thereto.

Regarding the soldering fastening element, the body has a shoulder for abutting against a surface of the first circuit board and has a second solder layer which a solder paste can be applied thereto.

Regarding the soldering fastening element, in that the second solder layer is an electroplated layer made of one of tin, copper, nickel and zinc.

Regarding the soldering fastening element, the body, the head and the neck are formed integrally or put together.

Regarding the soldering fastening element, the body and the neck are connected to thereby form a cylinder.

The soldering fastening element further comprises a carrier with a plurality of receiving spaces each having an opening, wherein the soldering fastening elements are passed through the openings in order to be disposed in the receiving spaces, respectively.

Regarding the soldering fastening element, the carrier has a lid whereby the opening is shut and opened.

In order to achieve the above and other objectives, the present invention provides a structure for soldering the soldering fastening element to a circuit board, the structure comprising: a first circuit board having a first solder layer; and a second board having an engaging portion, wherein the soldering fastening element is soldered to the first solder layer of the first circuit board, allowing the head of the soldering fastening element to be engaged with the engaging portion of the second board and the neck of the soldering fastening element to be penetratingly disposed in the engaging portion.

Regarding the structure for soldering the soldering fastening element to a circuit board, the first solder layer of the first circuit board has a solder tin layer soldered and thereby attached to the second solder layer of the soldering fastening element.

Regarding the structure for soldering the soldering fastening element to a circuit board, the first solder layer of the first circuit board has a surface copper layer, and the second solder layer of the soldering fastening element is soldered to the surface copper layer.

Regarding the structure for soldering the soldering fastening element to a circuit board, the first solder layer of the first circuit board has a surface copper layer, and the solder tin layer is soldered and thereby attached to the surface copper layer and the second solder layer of the soldering fastening element.

Regarding the structure for soldering the soldering fastening element to a circuit board, the soldering fastening element and the first circuit board together form a module member.

Regarding the structure for soldering the soldering fastening element to a circuit board, the engaging portion of the second board has a through hole of a diameter larger than the head and an engaging recess in communication with the through hole and of a width less than the head, wherein, after the head has passed through the through hole, the neck can be penetratingly disposed in the engaging recess.

Regarding the structure for soldering the soldering fastening element to a circuit board, the engaging portion of the second board has a through hole of a diameter larger than the head, an engaging hole of a diameter less than the head, and an engaging recess in communication with the through hole and the engaging hole and of a width less than the head, wherein, after the head has passed through the through hole, the neck 13 can be penetratingly disposed in one of the engaging recess or the engaging hole.

Regarding the structure for soldering the soldering fastening element to a circuit board, the first circuit board has a soldering recess such that the first solder layer is disposed inside the soldering recess, wherein the body of the soldering fastening element is soldered to the first solder layer inside the soldering recess.

In order to achieve the above and other objectives, the present invention provides a method for soldering the soldering fastening element to a circuit board, the method comprising the steps of: placing the soldering fastening elements in the receiving spaces of the carrier; taking the soldering fastening elements out of the receiving spaces of the carrier by allowing a tool to come into contact with the heads of the soldering fastening elements; transferring the soldering fastening elements to the first solder layer of the first circuit board; heating up a solder tin layer on the first solder layer such that the solder tin layer melts to become a liquid solder tin; and cooling down the liquid solder tin until it forms a solid soldering structure whereby the soldering fastening elements are soldered to the first circuit board.

Regarding the method for soldering the soldering fastening element to a circuit board, the solder tin layer is a soft solder tin.

### BRIEF DESCRIPTION OF THE DRAWINGS

FIG. 1 is a perspective view of a soldering fastening element formed integrally according to an embodiment of the present invention.

FIG. 2 is a front view of the soldering fastening element formed integrally according to an embodiment of the present invention.

FIG. 3 is a cross-sectional view of a head and a neck coupled thereto of the soldering fastening element according to an embodiment of the present invention.

FIG. 4 is a cross-sectional view of a body and the neck coupled thereto of the soldering fastening element according to an embodiment of the present invention.

FIG. 5 is a cross-sectional view of the head, the body and the neck coupled together of the soldering fastening element according to an embodiment of the present invention.

FIG. 6 is a cross-sectional view of the head, the body and the neck which mesh with each other according to an embodiment of the present invention.

FIG. 7 is a cross-sectional view of the soldering fastening element disposed at a carrier according to an embodiment of the present invention.

FIG. 8A is a schematic view of how to take the soldering fastening element out of the carrier with a tool according to an embodiment of the present invention.

FIG. 8B is a schematic view of how to transfer the soldering fastening element to the surface of a circuit board with a tool according to an embodiment of the present invention.

FIG. 8C is a schematic view of the soldering fastening element and the surface of a first circuit board which are heated up and soldered together according to an embodiment of the present invention.

FIG. 9A is a schematic view of how to transfer the soldering fastening element to an opening of the first circuit board with a tool according to an embodiment of the present invention.

FIG. 9B is a schematic view of the soldering fastening element and the opening of the first circuit board which are heated up and soldered together according to an embodiment of the present invention.

FIG. 10 is a cross-sectional view of a soldering recess of the first circuit board according to the present invention.

FIG. 11 is a cross-sectional view of the soldering recess of the first circuit board according to the present invention.

FIG. 12 is a perspective view of the soldering fastening element soldered to the first circuit board and coupled to the second board according to the present invention.

FIG. 13 is a cross-sectional view of the soldering fastening element soldered to the first circuit board and coupled to the second board according to the present invention.

FIG. 14 is a perspective view of a coupling portion of the second board according to another embodiment of the present invention.

FIG. 15 is a cross-sectional view of the coupling portion of the second board according to another embodiment of the present invention.

FIG. 16 is a perspective view of the carrier which is disk-shaped according to an embodiment of the present invention.

FIG. 17 is a schematic view of the carrier which is strip-shaped and curves to wind according to an embodiment of the present invention.

### DETAILED DESCRIPTION OF THE INVENTION

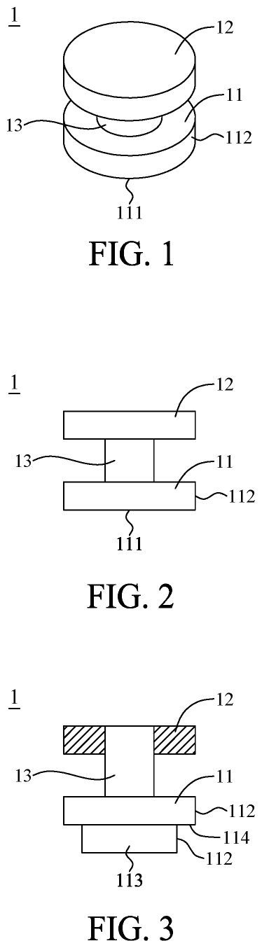

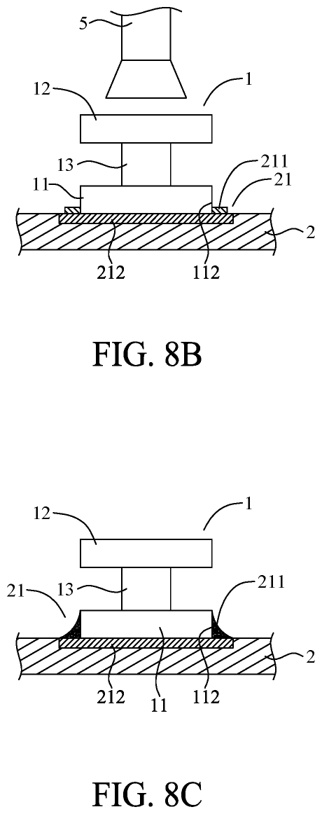

Referring to FIG. 1 and FIG. 2, there are shown a perspective view and a front view of the soldering fastening element formed integrally according to an embodiment of the present invention, respectively. The soldering fastening element 1 is soldered to a first circuit board 2, as shown in FIG. 8C, FIG. 11 and FIG. 13, and thus allows a second board 3 to be coupled thereto, as shown in FIG. 11 and FIG. 13. In a preferred embodiment, the soldering fastening element 1 is integrally formed and comprises a body 11 soldered to a first solder layer 21 of the first circuit board 2, a head 12 for fastening the second board 3 in place, and a neck 13 which connects the body 11 and the head 12. In this regard, the body 11 and the head 12 are round, polygonal, of a geometric shape, or of an atypical shape. The diameter of the neck 13 is less than that of the cylinder or polygonal post of the head 12 and the body 11.

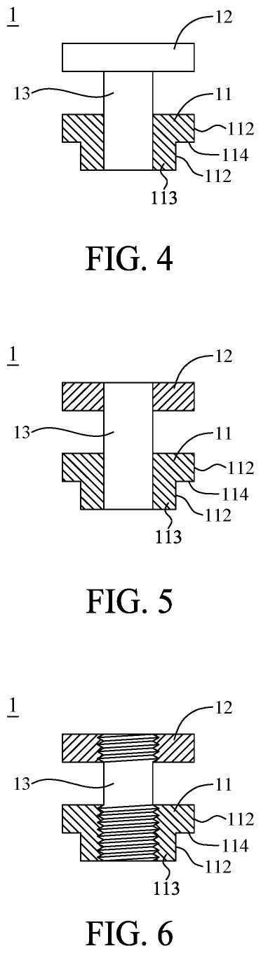

According to the present invention, the soldering fastening element 1 is not restricted to the aforesaid shapes. In various embodiments of the present invention, the soldering fastening element 1 is assembled rather than integrally formed. Referring to FIG. 3, the soldering fastening element 1 is characterized in that the body 11 and the neck 13 are integrally formed and then the other end of the neck 13 is coupled to the head 12. In another embodiment of the present invention, as shown in FIG. 4, the soldering fastening element 1 is characterized in that the head 12 and the neck 13 are integrally formed and then the other end of the neck 13 is coupled to the body 11. In yet another embodiment of the present invention, as shown in FIG. 5, the soldering fastening element 1 is characterized in that, the body 11, the head 12 and the neck 13 are separate and independent of each other in a manner that one end of the neck 13 is coupled to the body 11, and the other end of the neck 13 is coupled to the head 12. The present invention is not restrictive of the structures of the body 11, the head 12 and the neck 13 and the way of coupling the body 11, the head 12 and the neck 13 to each other, though FIG. 6 shows that riveting, tight assembly, and meshing are among the feasible options. Referring to FIG. 11, the soldering fastening element 1 is characterized in that the body 11 and the neck 13 are connected to thereby form a cylinder or integrally formed to thereby form a cylinder.

Referring to FIG. 1 and FIG. 2, the body 11 of the soldering fastening element 1 of the present invention has an engaging surface 111 for engaging with the surface of the first circuit board 2, whereas a second solder layer 112 is disposed at the periphery of the body 11 or disposed on the engaging surface 111. A solder paste can be applied to the second solder layer 112. Referring to FIG. 3, FIG. 4, FIG. 5 and FIG. 6, the body 11 of the present invention not only has a protruding portion 113 which is penetratingly disposed in an opening 22 of the first circuit board 2 but also has a shoulder 114 which abuts against the surface of the first circuit board 2, wherein the second solder layer 112 is also disposed at the periphery of the protruding portion 113 and/or the periphery of the shoulder 114 such that the solder paste can be applied to the second solder layer 112. The second solder layer 112 is an electroplated layer made of tin, copper, nickel or zinc such that the soldering fastening element 1 can be optimally soldered and coupled to the first circuit board 2.

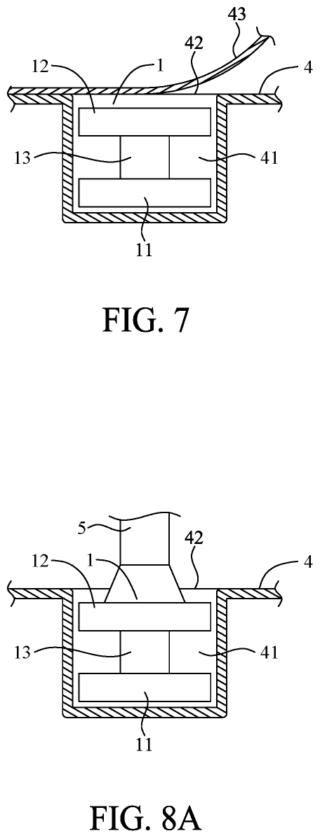

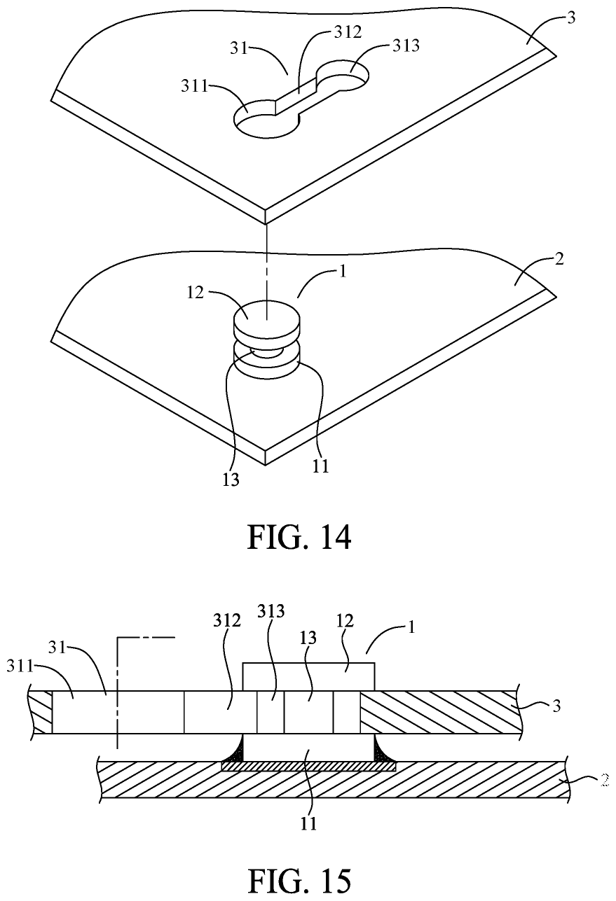

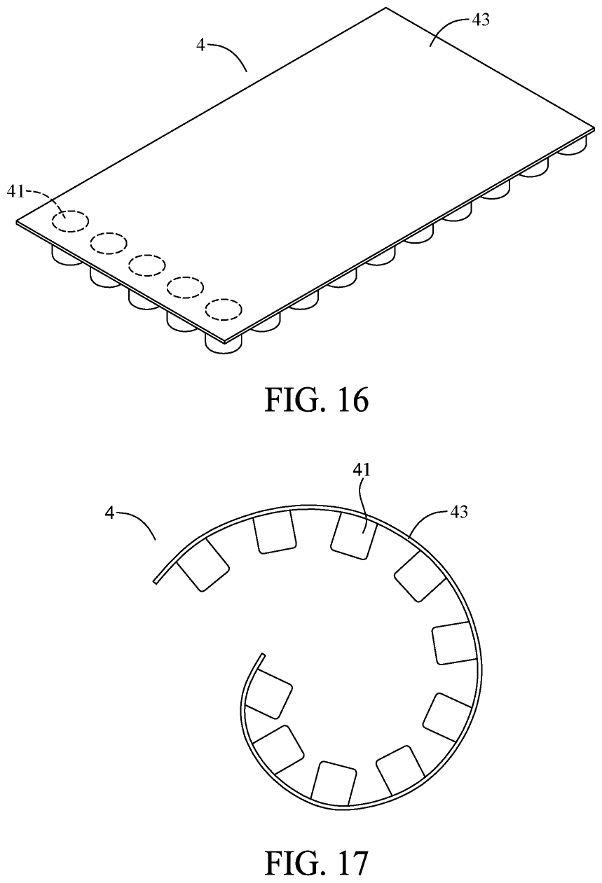

Referring to FIG. 7, after being manufactured or assembled in accordance with the aforesaid technical features, the soldering fastening element 1 is placed in a carrier 4. The carrier 4 is made of a plastic and has a plurality of receiving spaces 41. Each receiving space 41 has an opening 42 which comes with a lid 43 or a plastic membrane. The lid 43 or the plastic membrane enables the opening 42 to be shut and opened. In a variant embodiment of the present invention, the receiving spaces 41 are dispensed with the lids 43 and the plastic membranes. Hence, the soldering fastening elements 1 are passed through the openings 42 of the receiving spaces 41, with the bodies 11 facing the receiving spaces 41, and the heads 12 facing the openings 42, respectively, such that the soldering fastening elements 1 are aligned well and contained in the carrier 4. Hence, the soldering fastening elements 1 can be stored, transported, and taken out with a tool 5, as shown in FIG. 8A. Referring to FIG. 14, the carrier 4 is a rigid disk and defines a receiving space 41 for containing the soldering fastening element 1. Referring to FIG. 15, the carrier 4 is strip-shaped and curves to wind. The carrier 4 defines a receiving space 41 for containing the soldering fastening element 1.

Given the above technical features of the soldering fastening element 1 and the carrier 4, the present invention further provides a structure and method for soldering a soldering fastening element to a circuit board. Referring to FIG. 8A, a structure and method for soldering the soldering fastening element 1 to a circuit board entails allowing the tool 5 to come into contact with the head 12 of the soldering fastening element 1 and then taking the soldering fastening element 1 out of the receiving space 41 of the carrier 4. Referring to FIG. 8b, after being taken out of the receiving space 41 with the tool 5, the soldering fastening element 1 is transferred to the first solder layer 21 of the first circuit board 2 so as for the body 11 to abut against the first solder layer 21. Afterward, by undergoing a reflow soldering process or the like, a solder tin layer 211 on the first solder layer 21 melts to become a liquid solder tin. Then, the liquid solder tin keeps cooling down at room temperature until it forms a solid soldering structure whereby the soldering fastening element 1 and the first circuit board 2 are soldered together, and in consequence the soldering fastening element 1 and the first circuit board 2 together form a module member. At last, the second board 3 is fixed in place through the soldering fastening element 1. The tool 5 is preferably a suction cup for taking the soldering fastening element 1 out of the receiving space 41 of the carrier 4 as soon as it comes into contact with the head 12 of the soldering fastening element 1 before the soldering fastening element 1 is transferred to the first circuit board 2 to undergo a soldering process.

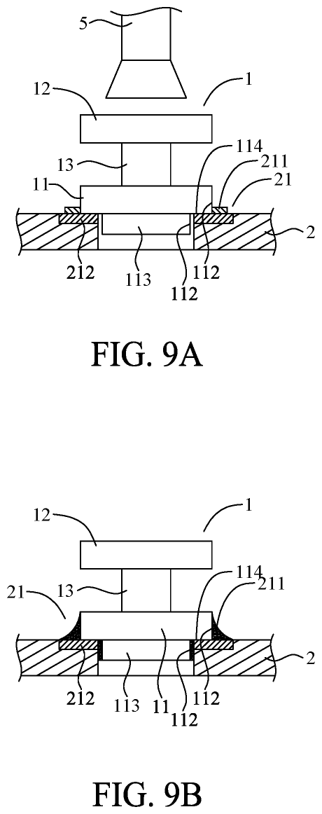

Referring to FIG. 9A and FIG. 9B, according to the present invention, the first circuit board 2 has the opening 22, wherein the first solder layer 21 is disposed at the periphery of the opening 22. With the method of the present invention, the soldering fastening element 1 is transferred to the first circuit board 2, and in consequence the protruding portion 113 of the body 11 of the soldering fastening element 1 can be inserted into the opening 22, whereas the shoulder 114 of the body 11 of the soldering fastening element 1 can abut against the opening 22 from the periphery thereof. Afterward, by undergoing a reflow soldering process or the like, a solder tin layer 211 on the first solder layer 21 melts to become a liquid solder tin. Then, the liquid solder tin keeps cooling down at room temperature until it forms a solid soldering structure whereby the soldering fastening element 1 and the first circuit board 2 are soldered together, and in consequence the soldering fastening element 1 and the first circuit board 2 together form a module member. Finally, the second board 3 is fixed in place through the soldering fastening element 1.

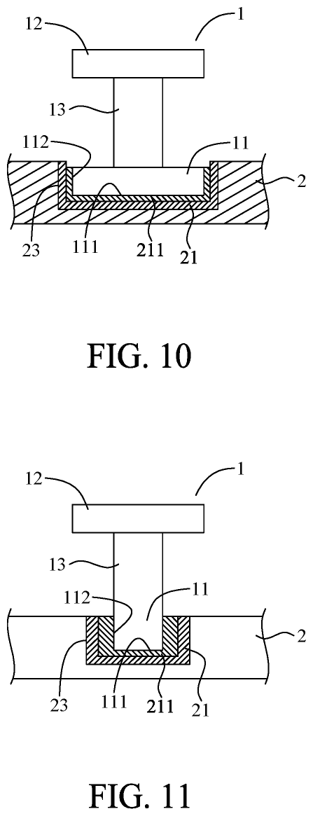

Referring to FIG. 8B or FIG. 9A, according to the present invention, the solder tin layer 211 is preferably formed on the first solder layer 21 of the first circuit board 2 in advance. Afterward, by undergoing a reflow soldering process or the like, the solder tin layer 211 melts and then solidifies so as to get soldered and thereby attached to the second solder layer 112 of the soldering fastening element 1. A surface copper layer 212 is disposed on the first solder layer 21 of the first circuit board 2. The second solder layer 112 melts and then solidifies so as to get soldered and thereby attached to the second solder layer 112 of the soldering fastening element 1 and the surface copper layer 212. The solder tin layer 211 is a soft solder tin, such as a solder paste, and is applied to the surface copper layer 212 or the opening 22 in advance in order to effectuate a soldering process performed on the soldering fastening element 1. Referring to FIG. 10 and FIG. 11, according to the present invention, the first circuit board 2 has a soldering recess 23 such that the first solder layer 21 is disposed inside the soldering recess 23 to take on an outline corresponding to that of the soldering recess 23. Then, the engaging surface 111 and the second solder layer 112 of the body 11 of the soldering fastening element 1 are soldered to the solder tin layer 211 on the first solder layer 21 inside the soldering recess 23, and in consequence the soldering fastening element 1 of the present invention can be firmly connected to the first circuit board 2.

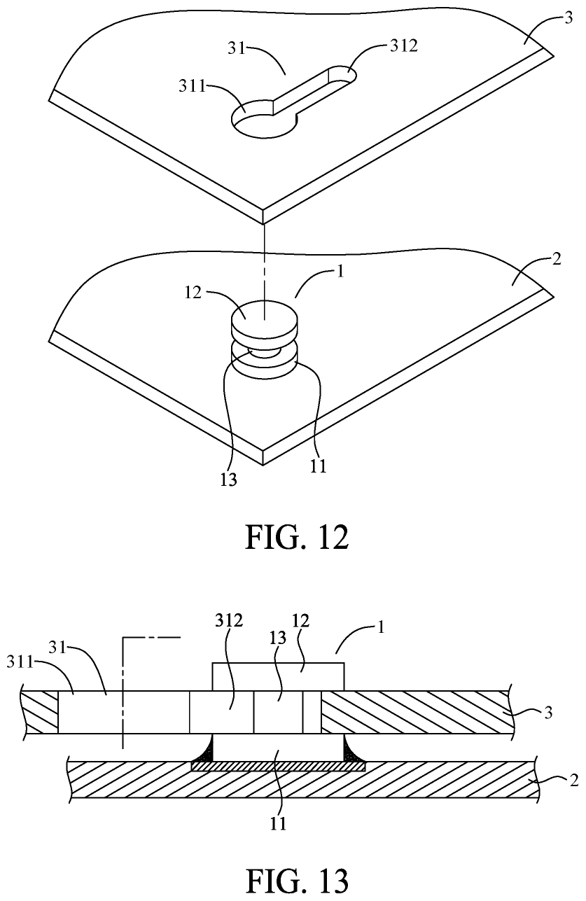

With the aforesaid structure and method for soldering a soldering fastening element to a circuit board, the soldering fastening element 1 and the first circuit board 2 together form a module member whereby the second board 3 is fixed in place through the soldering fastening element 1. Referring to FIG. 10 and FIG. 11, the second board 3 is an engaging portion 31 which matches the head 12 and the neck 13 of the soldering fastening element 1. The neck 13 of the soldering fastening element 1 is penetratingly disposed in the engaging portion 31, whereas the head 12 of the soldering fastening element 1 is engaged with the engaging portion 31. Referring to FIG. 10 and FIG. 11, the engaging portion 31 has a through hole 311 of a diameter larger than the head 12 and an engaging recess 312 in communication with the through hole 311 and of a width less than the head 12. Hence, after the head 12 of the soldering fastening element 1 has passed through the through hole 311, it is practicable for the second board 3 to be moved in a manner for the neck 13 to be penetratingly disposed in the engaging recess 312 so as to form a structure whereby the second board 3 is fastened in place. Referring to FIG. 12 and FIG. 13, the engaging portion 31 has a through hole 311 of a diameter larger than the head 12, an engaging hole 313 of a diameter less than the head 12, and an engaging recess 312 in communication with the through hole 311 and the engaging hole 313 and of a width less than the head 12. Hence, after the head 12 of the soldering fastening element 1 has passed through the through hole 311, it is practicable for the second board 3 to be moved in a manner for the neck 13 to be penetratingly disposed in the engaging recess 312 or the engaging hole 313 so as to form a structure whereby the second board 3 is fastened in place or otherwise move the second board 3 in the opposite direction to thereby separate the second board 3 from the soldering fastening element 1.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A structure for soldering a soldering fastening element to a circuit board, the soldering fastening element having a body, a head, and a neck for connecting the body and the head, the structure comprising:
a first circuit board having a first solder layer; and
a second board having an engaging portion,
wherein the body of the soldering fastening element is soldered to the first solder layer of the first circuit board, allowing the head of the soldering fastening element to be engaged with the engaging portion of the second board and the neck of the soldering fastening element to be penetratingly disposed in the engaging portion.

2. The structure according to claim 1, characterized in that the first solder layer of the first circuit board has a solder tin layer soldered and thereby attached to a second solder layer of the soldering fastening element.

3. The structure according to claim 1, characterized in that the first solder layer of the first circuit board has a surface copper layer, and a second solder layer of the soldering fastening element is soldered to the surface copper layer.

4. The structure according to claim 2, characterized in that the first solder layer of the first circuit board has a surface copper layer, and the solder tin layer is soldered and thereby attached to the surface copper layer and the second solder layer of the soldering fastening element.

5. The structure according to claim 1, characterized in that the soldering fastening element and the first circuit board together form a module member.

6. The structure according to claim 1, characterized in that the engaging portion of the second board has a through hole of a diameter larger than the head and an engaging recess in communication with the through hole and of a width less than the head, wherein, after the head has passed through the through hole, the neck can be penetratingly disposed in the engaging recess.

7. The structure according to claim 1, characterized in that the engaging portion of the second board has a through hole of a diameter larger than the head, an engaging hole of a diameter less than the head, and an engaging recess in communication with the through hole and the engaging hole and of a width less than the head, wherein, after the head has passed through the through hole, the neck can be penetratingly disposed in one of the engaging recess or the engaging hole.

8. The structure according to claim 1, characterized in that the first circuit board has a soldering recess such that the first solder layer is disposed inside the soldering recess, wherein the body of the soldering fastening element is soldered to the first solder layer inside the soldering recess.
